(19) United States
(12) Patent Application Publication
(10) Pub. No.: US 2003/0028841 A1
(43) Pub. Date: Feb. 6, 2003

(54) Data transfer device and method

(76) Inventors: Nigel Kevin Rushton, Bristol (GB); Laura Loredo Sierra, Bristol (GB); Paul Frederick Bartlett, Bristol (GB)

Correspondence Address: Thomas E. Anderson, Hunton & Williams, 1900 K Street, N.W., Washington,, DC, 20006-1109, US

(21) Appl. No.: 09/917,784

(22) Filed: Jul. 31, 2001

(51) Int. Cl. H03M 13/00

(52) U.S. Cl. 714/781; 360/90

(57) ABSTRACT

A data transfer device adapted to transfer data from a data storage medium having at least one data storage element the data transfer device comprising a head block having first and second transfer elements.

The first and second transfer elements arranged such that, when, in use, the data storage medium moves past the first and second transfer elements said at least one data storage element is aligned with both of said first and second data transfer elements. The first data transfer element is arranged to read data from a portion of said at least one data storage element at a different time to the second data transfer element being arranged to read data from said portion of said at least one data storage element.

### FIELD OF THE INVENTION

This invention relates to a data transfer device, and method of data transfer. More particularly, but not exclusively, it relates to a device and method for reading from a data storage medium with increased reliability.

### BACKGROUND TO THE INVENTION

Errors can occur when reading data from a medium. For example, if an error occurs when reading data from a tape it is usual to retry to read the data by rewinding the tape and running it past the read head again. This cycle can be repeated, for example, up to 56 times for a tape drive before the control unit reports an error to a user of the device. In hard disc drives there may be up to 100 retries prior to the reporting of an error to the user.

Typical contributing factors to the occurrence of read errors include: i) a read head being narrower than a data track and therefore not being able to read all of the data stored on the track; ii) a read head being wider than a data track and therefore picking up signals from a data track, or tracks, alongside that being read; iii) small particles of magnetic debris, from the surface of media or elsewhere, interposing in the small gap, typically a few μm, between the media and the head and interfering with the reading of the data.

Variations in the dimensions and magnetic properties of the read head due to variations in the production process and materials can cause i) and ii) above.

The use of data transfer devices, for example tape drives, comprising multiple heads is well known in order to increase data transfer rates by employing parallel data transfer channels. See for example FIG. 1, which shows a tape drive having multiple heads each reading a segment of a data file from a track on a tape.

The linear tape open (LTO) system typically employs a transfer device having a number of sets of paired read and write heads arranged in a read after write (RAW) configuration, as shown in FIG. 2, further details of which are disclosed in European Patent Application No. 99301353.1 (Publication No. EP0942427). This RAW configuration allows the transfer and immediate verification of data across eight data tracks irrespective of the direction of tape travel. The data transferred to the tape is retained in a buffer for a short period of time, typically a few seconds with the buffer being typically 2 Mbytes or more, the read heads following the write heads read the data written to the tape. A comparator compares the data stored in the buffer and that read from the tape, typically using a cycle redundancy check or a parity check. If an error is detected it is registered as a read after write error at a control unit.

These data transfer systems allow the verification of data written to a data storage medium and its re-writing to the medium if it is found that there is an error in writing the data. The control unit instructs the write head to re-write the flawed section of data to a different, downstream, part of the tape/disc.

### SUMMARY OF THE INVENTION

It is an object of at least one embodiment of the present invention to provide a data transfer device which, at least partly, ameliorates at least one of the above mentioned problems and, or, difficulties.

It is a further object of at least one embodiment of the present invention to provide a method of data transfer which, at least partly, ameliorates at least one of the above mentioned problems and, or difficulties.

According to a first aspect of the present invention there is provided a data transfer device adapted to transfer data from a data storage medium having at least one data storage element, the data transfer device comprising:

a head block having first and second transfer elements;

the first and second transfer elements arranged such that, when, in use, the data storage medium moves past the first and second transfer elements said at least one data storage element is aligned with both of said first and second data transfer elements; and

wherein the first data transfer element is arranged to read data from a portion of said at least one data storage element at a different time to the second data transfer element being arranged to read data from said portion of said at least one data storage element.

The data storage medium may be a magnetic tape. The data storage element may be a track which may be on the tape. The head block may be in a fixed position. The medium may be arranged to be rewound to enable the second transfer element to read said data from said portion of said at least one data storage element.

The first transfer element may be arranged to read data from said at least one data storage element. The second transfer element may be arranged to read data from said portion of the at least one data storage element if the first transfer element has failed to read data from said portion.

The device may include a processor, which may include a comparator arranged to compare a data element indicative of the data transferred from the first transfer element to a reference and execute an action should the data element and the reference not match. The device may be arranged such that the second transfer element reads data from the data storage element if the comparison fails.

The device may include a control unit. The transfer elements may be adapted to communicate with the control unit. The control unit may include at least one buffer. There may be provided more than one buffer and each buffer may be associated with at least one transfer element. Each buffer may be adapted to store temporarily data comnmunicated by the at least one transfer element, in use. The control unit may include a comparator. This comparator may be adapted to compare a data element indicative of the data transferred from the data storage element by the at least one transfer element to a data element of this data stored in the buffer associated with the at least one transfer element, in use.

The comparator may be arranged to execute at least one of the following error detection techniques upon the data, in use: cyclic redundancy checks, parity checks, non-correctable error detection codes, non-expandable data decompression codes.

The control unit may be situated within the data transfer device. Alternatively, it may be situated outside of it, for example, in a PC or a server. The control unit may be hardware, firmware or software enabled.

The medium may be a magnetic tape, a magneto-optical disc, a magnetic disc, a re-writeable C.D. or a mini-disc. The data transfer device may be a tape drive (either linear or helical), a magnetic disc drive, a C.D. drive or a mini-disc drive.

According to a second aspect of the present invention there is provided a data transfer device adapted to transfer data from a data storage medium having data storage elements;

the data transfer device comprising:

first and second data transfer elements;

a displacement element having a first condition and a second condition;

first and second transfer zones being adjacent the first and second transfer elements respectively when said displacement element is in said first condition;

and wherein the first transfer zone is arranged such that, when in use with the displacement element in said first condition, the data storage medium moves past the first and second transfer elements with first and second data storage elements aligned with said first and second transfer elements respectively; and

the displacement element being arranged to be moveable to said second condition in which, in use, relative displacement between at least a said transfer element and said transfer zones occurs such that a transfer zone that is aligned with one of said transfer elements when said displacement element is in said first condition is aligned with the other of said transfer elements, thereby enabling a said transfer zone to be alignable selectively with said first and said second data transfer elements at different times.

It will be understood that the term transfer zone is taken to mean an area adjacent a transfer element substantially defined by the transfer element's footprint.

The displacement element may be an electric motor, a solenoid, a stepper motor or a servomotor. The displacement element may be adapted to be actuable by a signal from a control unit. The displacement element may be adapted to act upon the transfer elements. Alternatively, the displacement element may be adapted to act upon the data storage medium. The displacement element may be adapted to displace the transfer elements relative to the data storage medium in response to the instruction, in use. The displacement element may be adapted to displace the transfer elements relative to the storage medium in a direction that is transverse to a direction of passage of the storage medium past the transfer elements, in use. For example it may displace the transfer elements in a direction that is generally perpendicular to the direction of motion of the storage medium in the vicinity of the transfer elements.

Preferably the transfer elements move as a unit relative to the storage medium, with no relative movement between transfer elements. However, in another embodiment there may be relative movement between transfer elements. For example, a transfer element may be arranged to move to read from a different track or channel on the storage medium, whilst other heads/transfer elements remain associated with an invariant channel/track.

The data storage medium may be a magnetic tape. The data storage element may be a track which may be on the tape. The medium may be arranged to be rewound such that one of said data transfer elements that passed either of the first or second transfer zones in the first condition, passes the other of the second or first transfer zones in the second condition.

The device may include a control unit. The transfer elements may be adapted to communicate with the control unit. The control unit may include at least one buffer. There may be provided more than one buffer and each buffer may be associated with at least one transfer element. There may be a respective buffer for each transfer element. Each buffer may be adapted to store temporarily data communicated by the at least one transfer element, in use. The control unit may include a comparator. This comparator may be adapted to compare a data element indicative of the data transferred from the data storage element by the at least one transfer element to a data element of this data stored in the buffer associated with the at least one transfer element, in use. Should the data elements not match the control unit may issue an instruction to the displacement element, in use. The comparator may be arranged to execute at least one of the following error detection techniques upon the data, in use: cyclic redundancy checks, parity checks, non-correctable error detection codes, non-expandable data decompression codes.

The control unit may be situated within the data transfer device. Alternatively, it may be situated outside of it, for example, in a PC or a server. The control unit may be hardware, firmware or software enabled.

The medium may be a magnetic tape, a magneto-optical disc, a magnetic disc, a re-writeable C.D. or a mini-disc. The data transfer device may be a tape drive (either linear or helical), a magnetic disc drive, a C.D. drive or a mini-disc drive.

According to a third aspect of the present invention there is provided a data transfer device having a data storage medium comprising:

a head block having first and second transfer elements;

both the first and second transfer elements being aligned with an at least one data storage element of said data storage medium; and

wherein the first data transfer element is arranged to read data from a portion of said at least one data storage element at a different time to the second data transfer element being arranged to read data from said portion of said at least one data storage element.

The second transfer element may be arranged to read data from said portion of the at least one data storage element if the first transfer element has failed to read data from said portion.

The device may include a processor, which may include a comparator arranged to compare a data element indicative of the data transferred from the first transfer element to a reference and execute an action should the data element and the reference not match. The device may be arranged such that the second transfer element reads data from the data storage element if the comparison fails.

The device may include a control unit. The transfer elements may be adapted to communicate with the control unit. The control unit may include at least one buffer. There may be provided more than one buffer and each buffer may be associated with at least one transfer element. There may be a respective buffer for each transfer element. Each buffer may be adapted to store temporarily data communicated by the at least one transfer element, in use. The control unit may include a comparator. This comparator may be adapted to compare a data element indicative of the data transferred from the data storage element by the at least one transfer element to a data element of this data stored in the buffer associated with the at least one transfer element, in use. Should the data elements not match the control unit may issue an instruction to the displacement element, in use. The comparator may be arranged to execute at least one of the following error detection techniques upon the data, in use: cyclic redundancy checks, parity checks, non-correctable error detection codes, non-expandable data decompression codes.

The control unit may be situated within the data transfer device. Alternatively, it may be situated outside of it, for example, in a PC or a server. The control unit may be hardware, firmware or software enabled.

The medium may be a magnetic tape, a magneto-optical disc, a magnetic disc, a re-writeable C.D. or a mini-disc. The data transfer device may be a tape drive (either linear or helical), a magnetic disc drive, a C.D. drive or a mini-disc drive.

According to a fourth aspect of the present invention there is provided a data transfer device having a data storage medium comprising;

a head block having first and second transfer elements;

a displacement element;

the first transfer element arranged to transfer data between the head block and a data storage element of the data storage medium;

the displacement element being actuable to achieve relative displacement between the head block and the data storage medium such that following displacement the second transfer element is arranged to transfer data between the head block and the data storage element.

Should a read error of data stored on the medium occur this arrangement allows a read retry to be attempted using a different read head than that which registered the error thus overcoming, at least partially, at least one of the problems/difficulties mentioned hereinbefore.

The displacement element may be an electric motor, a solenoid, a stepper or a servomotor. The displacement element may be be adapted to be actuable by a signal from a control unit. The displacement element may be adapted to act upon the head block. Alternatively, the displacement element may be adapted to act upon the data storage medium. The displacement element may be adapted to displace the head block relative to the data storage medium in response to an instruction, in use. The displacement element may be adapted to displace the head block relative to the storage medium in a direction that is transverse to a direction of passage of the storage medium past the head block, in use.

The transfer elements may be write heads, read heads or a combination of both read and write heads. The transfer elements may be arranged in a read after write configuration. These alternatives allow the data to be either re-read or re-written using different heads thereby increasing the likelihood of an apparently errored section of data storage medium being successfully read.

The device may include a control unit. The head block may communicate with the control unit. The control unit may include a buffer. There may be provided a plurality of buffers and each buffer may be associated with at least one transfer element. Each buffer may be adapted to store temporarily data communicated to the at least one transfer element, in use. The control unit may include a comparator. This comparator may be adapted to compare a data element indicative of the data transferred to the data storage element by the at least one transfer element to a data element of this date stored in the buffer associated with the at least one transfer element, in use. Should the data elements not match the control unit may issue an instruction to the displacement element, in use.

The control unit may be situated within the data transfer device. Alternatively, it may be situated outside of it, for example, in a PC or a server. The control unit may be hardware, firmware or software enabled.

The head block may include 2 or more, typically 4, 8, 12, 16 or more data transfer elements or any multiple thereof.

The medium may be a magnetic tape, a magneto-optical disc, a magnetic disc, a re-writeable C.D. or a mini-disc. The data transfer device may be a tape drive, a magnetic disc drive, a C.D. drive or a mini-disc drive.

According to a fifth aspect of the present invention there is provided a method of reading data from a data storage medium comprising the steps of:

i) providing a plurality of data transfer elements;

ii) reading said data from a data storage element of the storage medium via a first data transfer element;

iii) error checking a data element indicative of the data read from the storage medium via the first data transfer element;

iv) reading said data from the data storage medium via a second data transfer element if the comparison of step iii) results in an error signal.

The method may include aligning the second transfer element with both the first transfer element and the data storage element and may include having the plurality of data transfer element in a fixed position.

The method may include actuating a displacement element so as to effect a relative displacement of the storage medium and the plurality of data transfer elements.

The method may comprise the step of displacing the storage medium relative to the plurality of data transfer elements such that the second transfer element is arranged to read said data. The method may comprise the displacement element acting upon the data transfer elements. The method may comprise the displacement element acting upon the data storage medium. The method may comprise the step of providing the displacement element in the form of an electric motor, a solenoid, a stepper or a servomotor.

Step iii) of the method may comprise the executing of a cyclic redundancy check upon said data elements or it may comprise executing a parity check, non-correctable error detection code check or a non-expandable data decompression check.

The method may comprise the step of executing steps ii) and iii) up to a pre-determined number of times prior to executing step iv) if the initial repetition of steps iii) and iv) does not avoid the production of an error signal, and preferably not executing step iv) if any one of the comparisons results in a match. The method may further comprise executing steps ii) and iii) up to any one of the following numbers of times: <10, 56, 100, 250, >250.

The method may comprise reporting a read error to a user of the storage medium if steps i) to iv) of the method are repeated more than a pre-determined number of times during a single read operation, which may lie between any one of the following range of values 1, 4, 8, 16, 32, >32.

The method may comprise providing the storage medium in any one of the following formats: magnetic tape, magnetic disc, magneto-optical disc, re-writeable CD, mini-disc.

According to a sixth aspect of the present invention there is provided a program storage device readable by a machine and encoding a program of instructions which when operated upon the machine cause the machine to operate as the device according to the first, second, third or fourth aspects of the present invention.

According to a seventh aspect of the present invention there is provided a computer readable medium having stored therein instructions for causing a device to execute the method of fifth aspect of the present invention.

According to an eighth aspect of the present invention there is provided a machine readable data carrier having encoded upon it instructions to control a control processor of a data transfer device having first and second read/write data transfer heads, a data recording medium having a read/write zone adjacent the heads, a multi-channel recording medium provided in the zone adjacent the heads, and a head to channel alignment device adapted to control the relative position, transverse to the direction of movement of the medium past the heads, of the heads and the channels of the medium, the instructions causing the control processor to read or write data to or from a channel on the recording medium and to check the read or written data for errors, and upon detecting an error the instructions causing the control processor to control the alignment device to align the channel which caused the error signal with a different head to that which was used in the read/write operation which resulted in an error signal.

The alignment adjustment may be relative movement of the head with a different channel, or in the case where there is more than one head associated with the same channel, aligning a portion of the medium with a different head on the same channel.

According to a ninth aspect of the present invention there is provided a method of reading data from a data carrier using a device with first and second data transfer heads arranged in a read-after-write configuration with both heads aligned with a common data track comprising attempting to read the data from the data carrier using the first head and subsequently reading the data using the second head.

Preferably the second head is used to read the data if the first head has difficulty reading it.

Preferably the second head is a write head capable of writing data to the carrier as well as reading data from the data carrier.

Preferably the method comprises determining that the first head has not read data of a region of the data carrier properly and advancing or rewinding said region to align it with the second head.

Preferably the data carrier comprises a tape which moves past the second head before encounters the first head and the tape is rewound in order to read a section of the tape with the second head.

According to a tenth aspect of the present invention there is provided a data transfer device arranged to read data from a data carrier comprising data transfer heads arranged in a read-after-write configuration having both heads arranged to be aligned with a common data track of the data carrier, the first head arranged to read data from the data carrier and the second head subsequently arranged to read data from the data carrier.

Preferably the second head is arranged to read the data if the first head has difficulty reading it.

Preferably the second head is a write head arranged to be capable of both reading and writing from/to the data carrier.

Preferably the device is arranged to determine that the first head has not read data of a region of the data carrier properly and advancing, or rewinding, said region to align it with the second head.

Preferably the data carrier is a tape which is arranged to move past the second head prior to encountering the first head and the tape is rewound in order to read a section of the tape with the second head.

According to an eleventh aspect of the present invention there is provided a data transfer device arranged to read data from a data carrier, the device comprising:

first and second read heads arranged to be aligned with a single track of said data carrier;

the first read head being arranged to read data from said track; and

the second read head being arranged to read said data from said track.

The second read head may be arranged to read said data only if said first read head has failed to read said data. The first read head may lie downstream of the second read head and it may be necessary to rewind the necessary part of the tape to the about first read head if the first read head fails to read said data. The second read head may read the data from the tape with the tape travelling in the same direction as when the first read head reads said data or it may read the data with the tape travelling in the opposite direction as when the first read head reads said data.

The second read head may be both a read head and a write head. The first and second read heads may be configured in a read after write arrangement and the head normally configured to write data may also be configured to read data as the second read head. The device may have both a read after write mode, in which the second head writes data and the first head reads data, and a read retry mode in which the second head reads data after the first head has failed to read the data.

### BRIEF DESCRIPTION OF THE DRAWINGS

The invention will now be described, by way of example only, with reference to the accompanying drawings, in which:

FIG. 1 is a representation of a prior art multi-head parallel track tape drive and tape;

FIG. 2 is a representation of a prior art head assembly for an eight-track ‘read after write’ tape drive;

FIG. 3 is a schematic representation of a tape drive incorporating a data transfer device according to a first aspect of the present invention and a tape;

FIG. 4 is a schematic representation of a tape drive incorporating a data transfer device according to an aspect of the present invention and a tape;

FIG. 5 is a schematic representation of the tape drive of FIG. 4 in an alternative agreement;

FIG. 6 is a schematic representation of the tape drive of FIG. 4 in a further alternative arrangement;

FIG. 7 is a sectional view of a head block and displacement element arrangement of the tape drive of FIG. 4;

FIG. 8 is a sectional view of an alternative head block and displacement element arrangement of the tape drive of FIG. 4;

FIG. 9 is a flow chart detailing a further method of data transfer according to an aspect of the present invention;

FIG. 10 is a schematic representation of a CD rewriter incorporating a data transfer device according to an aspect of the present invention and a writeable CD;

FIG. 11 is a schematic representation of a magnetic disc drive incorporating a data transfer device according to an aspect of the present invention and a magnetic disc; and

FIG. 12 is a representation of a data carrier carrying software or program instructions in accordance with any one of the fifth, sixth or seventh aspects of the present invention.

### DETAILED DESCRIPTION OF THE INVENTION

It will be appreciated that the following description of preferred embodiments of the invention is exemplary only and is intended to provide a thorough understanding. It will further be appreciated by one skilled in the art that the present invention may be executed without limitation to the embodiments described hereinafter and that well-known methods and structures have not been described hereinafter, so as not to unnecessarily obscure the present invention.

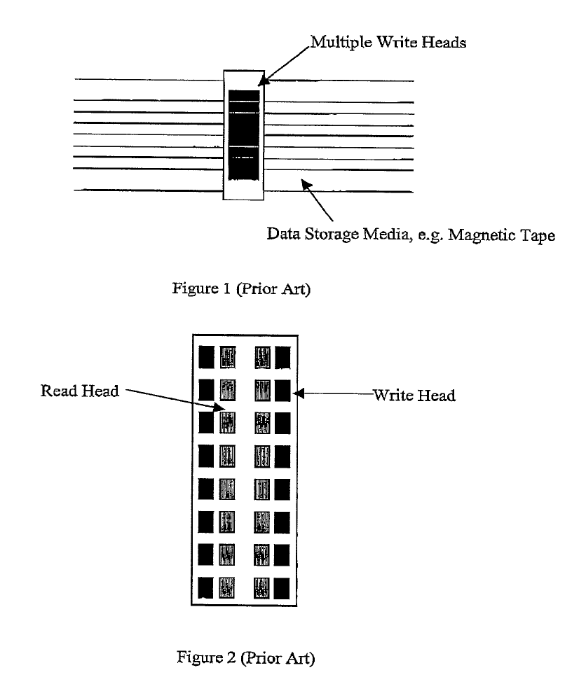

FIGS. 1 and 2 disclose prior art arrangements of multiple data transfer heads and are discussed further in the ‘Background to the Invention’.

The specific methods and advice according to the first embodiment of the present invention described herein are concerned with magnetic tape recording devices having substantially static, aligned read/write heads in which elongate tape is drawn past the heads in a direction transverse to axis of alignment of the heads.

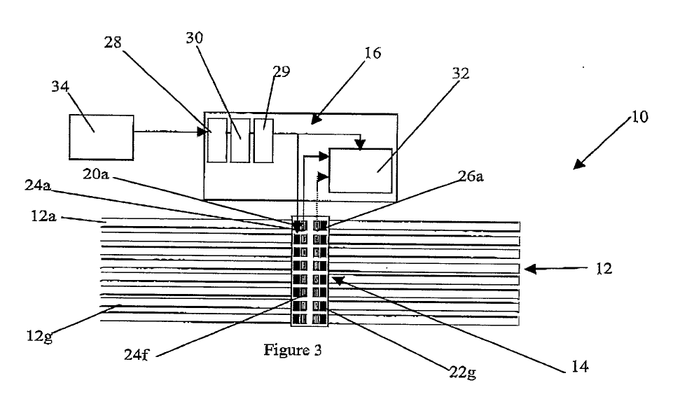

Referring now to FIG. 3, a magnetic tape reader 10 arranged to read a tape 12 includes a head block 14 and a control unit 16.

The tape 12 has a plurality of physical data tracks 12a-h that extend over its length. It will be appreciated that although eight tracks are shown there will be many more physical data tracks, typically up to 512 present on the tape 12. Each tape 12 will have a servo track that is written onto the blank tape during manufacture which actively controls the motion of the head block 14 over the tape. The servo track is typically bound and runs parallel to each set of eight tracks 12a-n.

The head block 14 has two parallel columns of eight write heads 20a-h, 22a-h lying transversely to the length of the tape 12. Each write head 20a-h, 22a-h has a read head 24a-h, 26a-h associated with it. The read heads 24a-h, 26a-h are arranged between the columns of write heads 20a-h, 22a-h such that whichever direction the tape is run a read head follows a write head.

The control unit 16 includes a data partitioner 28, a buffer 29, a data distributor 30 and a verification unit 32.

The control unit 16 receives data from a data source 34. The data source 34 is typically a server, PC or network. The data passes to the data partitioner 28 where it is divided into data segments, such as codeword quads (CQ), as disclosed in European Patent Application No. EP 0 942 427.

The arrangement of the write and read heads 20a-h and 24a-h allows data segments (such as CQs) written by the write heads 20a-h to be verified by the read heads 24a-h. Should the written data exhibit a read-write error during the verification process it can be re-read by the same read head, typically up to 56 times. This corresponds to the known read after write process. Similarly, the read heads 26a-h verify data written by the write heads 22a-h.

The data segments are copied in to the buffer 29 and pass from the partitioner 28 to the data distributor 30 which allocates the data segments to the write heads 20a-h and passes them thereto. The parallel transcription of the data to the tracks 12a-h of the tape 12 increases the rate of data transfer from the control unit 16 to the tape 12 over serial transcription arrangements.

Write head 20a attempts to write the data segment to the track 12a. The read head 24a attempts to read this data segment from the track 12a. The data segment retrieved from the track 12a is passed to the verification unit 32 where it is compared to the data segment passed from the distributor 30. The comparison may be a direct comparison of the retrieved data segment to that passed from the distributor 30 and retained in the buffer 29 or it may be a cyclic redundancy check.

Should the verification unit establish that the data segment has been successfully written to the track 12a the data continues to be written, in the normal manner as disclosed in EP 0 942 427. If the data segment is not successfully written to the track 12a, the tape is rewound and the data is rewritten to the track 12a using the head 20a.

In a first embodiment of the of the present invention as shown in FIG. 3, when reading previously recorded data from a tape 12 the tape 12 passes the head block 14, which is stationary, such that both respective primary and secondary read heads 24a-h, 26a-h are aligned with respective tracks 12a-h.

In the example shown, the primary read head 24a attempts to read a data segment from the track 12a. The verification unit 32 carries out an error detection routine on the data segment read by the head 24a. The error detection routine will typically be a cyclic redundancy check, a parity check, a non-correctable error detection code check or a non-expandable data compression check.

Should the verification unit 32 return an error signal, the control unit 16 issues an instruction that the tape 12 be drawn back and the primary read head 24a re-reads the data segment. The verification unit 32 executes an error detection routine on this data segment re-read by the primary read had 24a. This cycle is repeated a predetermined number of times, typically 56 for a tape drive, or until the data segment is read successfully. If the data cannot be read successfully using the primary read head 24a, the tape 12 is rewound and read-verification cycles are executed using the secondary read head 26a.

If the data is read successfully using either of the primary or secondary read heads 24a, 26a, reading of data segments from the track 12a using the primary read head 24a continues as normal. However, if the data segments cannot be read using either the primary or the secondary read heads 24a, 26a the control unit 16 reports a read error to a user or device.

It will be appreciated that the second read head may read data with the tape running in either the same or the opposite direction of travel to that in which the first head reads data.

It will further be appreciated that the data may have been written to the tape by any suitable device having a write capability, it need not be written by the device upon which the data is being read.

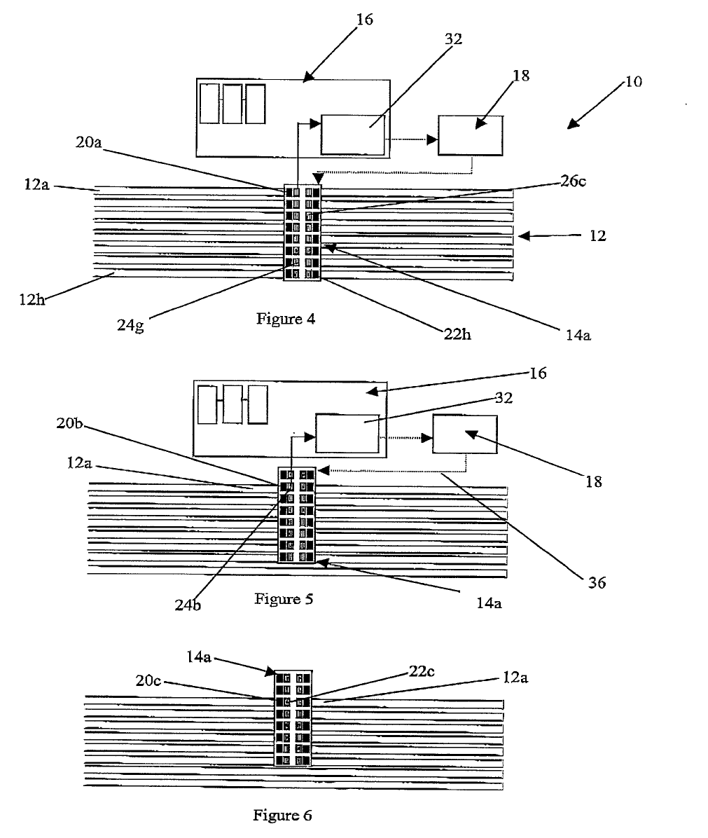

In an alternative arrangement, as shown in FIG. 4 in which similar parts to those of FIG. 3 are accorded the same reference numerals, when reading the data that has previously been written to the tape 12, the verification unit 32 executes an error detection routine in order to establish if a read error has occurred for each data segment read by each of the read heads 24a-h, 26a-h.

In the example shown read head 24a attempts to read data from the track 12a. If an error is noted the device 10 will retry reading the data segment with the read head 24a, typically a further 55 times for tape. After a number of unsuccessful attempts at reading the data segment (e.g. CQ) using the read head 24a a signal 36 is passed to a servo 18 which repositions a head block 14a, which is moveable relative to the tape 12 in a direction transverse to the direction of travel of the tape 12, such that the read head 24b is positioned to be able to read the track 12a (see FIG. 5).

The tape 12 is rewound and the read head 24b reads the portion of track 12a that contains the data segment initially read by the read head 24a. The data segment retrieved by the read head 24b is passed to the verification unit 32 for comparison using an error detection routine as hereinbefore described. If after a number of unsuccessful attempts to read the data segment written to track 12a using the read head 24b the servo motor 18 repositions the head block 14a such that read head 24c is positioned to be able to read that portion of the track 12a initially read by the read head 24a and the read process is repeated, see FIG. 6.

Once the data segment has been successfully read, for example by the read head 24f, the head block 14a returns to its original position, i.e. read head 24a aligned with track 12a, and the reading of data continues.

The read process may be repeated until all of the read heads 24a-h and/or the read heads 26a-h have failed to read the data successfully before a read error is reported to a user of the device typically via a user interface such as a display panel or a computer screen. Alternatively any number of read heads up to the maximum number available may be tried prior to reporting a read write error. The number of read heads to be used prior to registering an error may be defined by the control unit 16, an external device such as a PC or server, or by software running on said control unit or external device. This arrangement will be particularly applicable where there is provided more than one servo track on a tape which will allow head block movement.

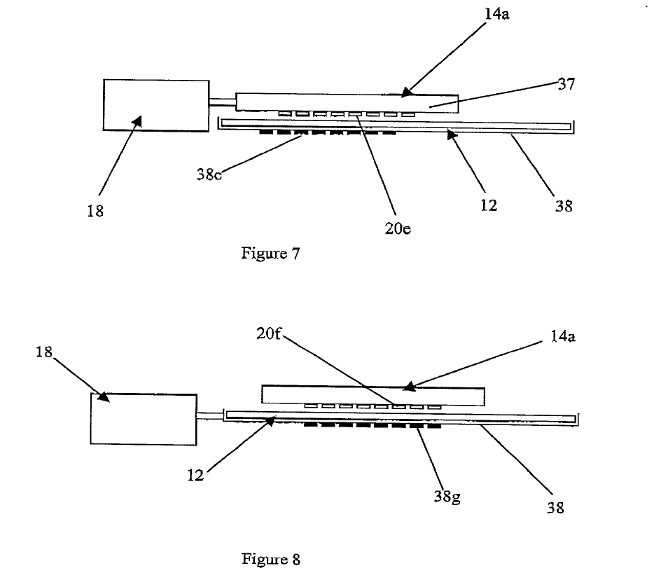

FIG. 7 shows the tape 12 and the head block 14a connected to the servo 18. The head block 14a comprises a head mounting frame 37, a tape guide 38 and the write and read heads 20a-h, 22a-h and 24a-h, 26a-h.

The servo 18 is arranged to displace the head block 14a transversely with respect to the direction of passage of the tape 12 past the head block 12. This enables the any given read head 24a-h, 26a-h to be aligned with any given track 12a-h of the tape 12.

FIG. 8 shows an alternative displacement arrangement to that of FIG. 7 wherein the head block 14a remains stationary and the servo 18 displaces the tape 12 relative to the head block 14a by means of the tape guide 38.

It will be appreciated that the second read head may read data with the tape running in either the same or the opposite direction of travel to that in which the first head reads data.

It will further be appreciated that the data may have been written to the tape by any suitable device having a write capability, it need not be written by the device upon which the data is being read.

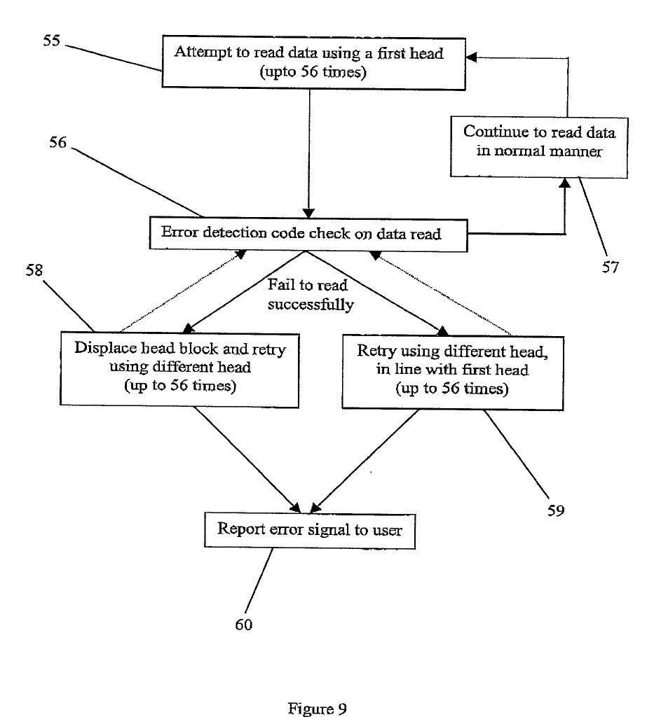

Referring now to FIG. 9, a flowchart detailing a method of data transfer, an attempt is made to read data using a first read head 24a (Step 55). An error detection check is made by a processor 32 on the data read by the first read head 24a (Step 56). If the error detection check is successful the data continues to be read in the normal manner (Step 57). However, if the data is not successfully read using the first head 24a a number of retries, typically 56 for a tape device, are made using the first head 24a. If the data has not been successfully read after a number of retries, typically 56 for tape, the data is attempted to be read by another head.

In the first embodiment of the present invention described hereinbefore the re-reading of the portion of the tape initially read by the first head 24a by another head involves using a further read head 26a that is aligned with the first read head 24a and the track 12a that contains the data that is being read. The tape is rewound and the head 26a attempts to read the data (Step 59). The re-read data undergoes an error detection code check as described hereinbefore (Step 56).

In the second embodiment of the present invention described hereinbefore the re-reading of the portion of the tape initially read by the first head 24a by another head involves effecting a relative displacement between the head block 14 and tape 12 by the servo 18. This displacement aligns a second read head 26b that is spaced apart from the first head in a direction that is transverse to the direction of travel of the tape with the track 12a, the tape is rewound and the head 26b attempts to read the data (Step 58). The re-read data undergoes an error detection code check as described hereinbefore (Step 56). Numerous attempts to read the data can be made using numerous read heads by repeatedly displacing the head block 14a.

If after a number of retries using the second head 26b, 26a the data has still not been successfully read the tape drive 10 returns a read error signal to a user (Step 60).

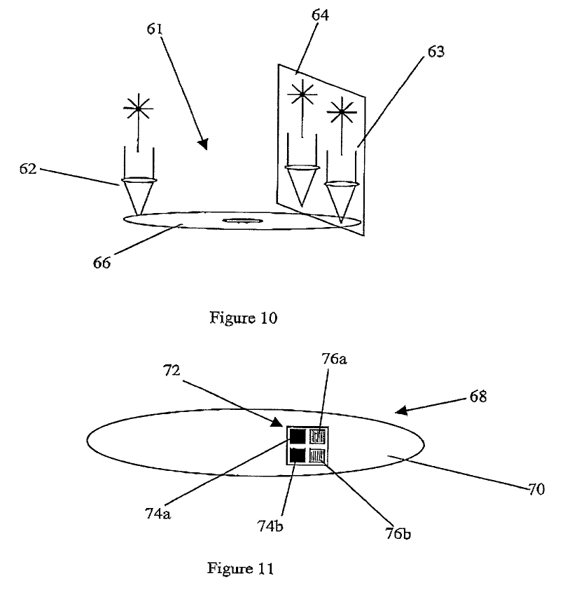

In a further embodiment of the present invention, shown in FIG. 10, a CD re-writer 61 includes write optics 62 and two sets of read optics 63, 64. A first set of the read optics 63 is used to attempt to read data written to a CD 66 by the write optics 62. If the data cannot be read by the first set of read optics 63 after a suitable number of retries, the second set of read optics 64 attempts to read said data. If the data cannot be read the re-writer 58 logs an error.

In a yet further embodiment of the present invention, shown in FIG. 11, a hard disc drive 68 comprises a hard disc 70 and a head block 72. The head block 72 includes two write heads 74a, 74b and two read heads 76a, 76b.

Data having been written to the disc 70 is initially read and verified using the read head 76a. However, if a read error is noted when reading the data using the read head 76a, after a suitable number of retries, typically of the order of 100, the head block 72 is repositioned with the second read head 76b over the data. The second read head 76b is used to attempt to read the data. If the second read head 76b cannot successfully read the data an read error is returned to the user of the drive 68.

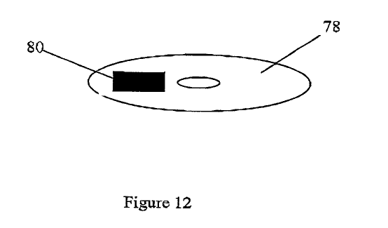

FIG. 12 shows a data carrier 78 bearing coded instructions 80 for making a device operate as described hereinbefore and/or execute a method as described hereinbefore.

Although shown as a disc it will be appreciated that the data carrier may take any convenient form including, but not exclusively limited to, a magnetic disc, a magneto-optical disc, a CD, a mini disc or a magnetic tape.

We claim:

1. A data transfer device adapted to transfer data from a data storage medium having at least one data storage element, the data transfer device comprising:
a head block having first and second transfer elements;
the first and second transfer elements arranged such that, when, in use, the data storage medium moves past the first and second transfer elements said at least one data storage element is aligned with both of said first and second data transfer elements; and
wherein the first data transfer element is arranged to read data from a portion of said at least one data storage element at a different time to the second data transfer element being arranged to read data from said portion of said at least one data storage element.

2. A data transfer device according to claim 1 wherein the data storage medium is a magnetic tape.

3. A data transfer device according to claim 2 wherein the data storage element is a track on the tape.

4. A data transfer device according to claim 1 wherein the head block is in a fixed position.

5. A data transfer device according to claim 1 wherein the medium is arranged to be rewound to enable the second transfer element to read said data from said portion of said at least one data storage element.

6. A data transfer device according to claim 1 wherein the second transfer element is arranged to read data from said portion of the at least one data storage element if the first transfer element has failed to read data from said portion.

7. A data transfer device according to claim 1 wherein the device includes a control unit with which the transfer elements are adapted to communicate, said control unit being adapted to determine whether said first transfer element has failed to read said data from said portion.

8. A data transfer device according to claim 7 wherein the control unit includes a comparator arranged to execute at least one of the following error detection techniques upon the data read by said first data transfer element:
i) cyclic redundancy checks
ii) parity checks
iii) non-correctable error detection codes
iv) non-expandable data decompression codes

9. A data transfer device according to claim 8 wherein the second transfer element is arranged to read data from said portion of the at least one data storage element if the data read by the first transfer element fails any one of the error detection techniques of claim 8.

10. A data transfer device according to claim 1 wherein the data storage medium is any one of the following:
i) a magneto-optical disc
ii) a magnetic disc
iii) a C.D.
iv) a mini-disc.

11. A data transfer device according to claim 1 wherein the device is any one of the following:
i) a linear tape drive
ii) a helical tape drive
iii) a magnetic disc drive,
iv) a C.D. drive
v) a mini-disc drive.

12. A data transfer device adapted to transfer data from a data storage medium having data storage elements;
the data transfer device comprising:
a displacement element having a first condition and a second condition;
first and second transfer zones being adjacent the first and second transfer elements respectively when said displacement element is in said first condition;
and wherein the first transfer zone is arranged such that, when in use with the displacement element in said first condition, the data storage medium moves past the first and second transfer elements with first and second data storage elements aligned with said first and second transfer elements respectively; and
the displacement element being arranged to be moveable to said second condition in which, in use, relative displacement between at least a said transfer element and said transfer zones occurs such that a transfer zone that is aligned with one of said transfer elements when said displacement element is in said first condition is aligned with the other of said transfer elements, thereby enabling a said transfer zone to be alignable selectively with said first and said second data transfer elements at different times.

13. A data transfer device according to claim 12 wherein the data storage medium is a magnetic tape.

14. A data transfer device according to claim 12 wherein the data storage element may be a track which may be on the tape.

15. A data transfer device according to claim 12 wherein the medium is arranged to be rewound such that one of said data transfer elements that was passed either of the first or second transfer zones in the first condition passes the other of the second or first transfer zones in the second condition.

16. A data transfer device according to claim 12 wherein said displacement element is adapted to displace the transfer elements relative to the data storage medium.

17. A data transfer device according to claim 12 wherein said displacement element is adapted to displace said transfer elements relative to the storage medium in a direction that is transverse to a direction of passage of the storage medium past the transfer elements, in use.

18. A data transfer device according to claim 12 wherein the device includes a control unit and the transfer elements are arranged to communicate with the control unit, said control unit being adapted to determine whether said first transfer element has failed to read data from said portion

19. A data transfer device according to claim 18 wherein the control unit are a plurality of buffers and each buffer is adapted to store, temporarily, data communicated between the storage element and at least one of the transfer elements.

20. A data transfer device according to claim 19 wherein control unit includes a comparator which is adapted to compare a data element indicative of the data transferred from the data storage element by the at least one transfer element to a data element of the data stored in the each buffer associated with the at least one transfer element, in use.

21. A data transfer device according to claim 12 wherein the data storage medium is selected from the following list:
i) a magneto-optical disc
ii) a magnetic disc
iii) a re-writeable C.D.
iv) a C.D.
v) a mini-disc

22. A data transfer device according to claim 12 wherein the data transfer device is selected from the following list:
i) a linear tape drive
ii) a helical tape drive
iii) a magnetic disc drive
iv) a C.D. drive
v) a mini-disc drive

23. A data transfer device having a data storage medium comprising:
a head block having first and second transfer elements;
both the first and second transfer elements being aligned with a data storage element of said data storage medium; and
wherein the first data transfer element is arranged to read data from a portion of said at least one data storage element at a different time to that at which the second data transfer element is arranged to read data from said portion of said at least one data storage element.

24. A data transfer device according to claim 23 wherein the second transfer element is arranged to read data from said portion of the at least one data storage element if the first transfer element has failed to read data from said portion.

25. A data transfer device according to claim 23 wherein the device includes a control unit with which the transfer elements are adapted to communicate.

26. A data transfer device according to claim 25 wherein the control unit includes a comparator arranged to execute at least one of the following error detection techniques upon the data read by said first data transfer element:
1) cyclic redundancy check
ii) parity check
iii) non-correctable error detection code
iv) non-expandable data decompression code

27. A data transfer device according to claim 26 wherein the second transfer element is arranged to read data from said portion of the at least one data storage element if the data read by the first transfer element fails any one of the error detection techniques of claim 26.

28. A data transfer device according to claim 23 wherein the data storage medium is any one of the following:
i) a magnetic tape
ii) a magneto-optical disc
iii) a magnetic disc
iv) a C.D.
v) a mini-disc.

29. A data transfer device according to claim 23 wherein the device is any one of the following:
i) a linear tape drive
ii) a helical tape drive
iii) a magnetic disc drive,
iv) a C.D. drive
v) a mini-disc drive.

30. A data transfer device having a data storage medium,
a head block having first and second transfer elements;
a displacement element;
the first transfer element arranged to transfer data between the head block and a data storage element of the data storage medium;
the displacement element being actuable to achieve relative displacement between the head block and the data storage medium such that following displacement the second transfer element is arranged to transfer data between the head block and the data storage element.

31. A data transfer device according to claim 30 wherein the displacement element is adapted to displace the head block relative to the data storage medium in response to the instruction, in use.

32. A data transfer device according to claim 30 wherein the displacement element is adapted to displace the head block relative to the storage medium in a direction that is transverse to a direction of passage of the storage medium past the transfer elements, in use.

33. A data transfer device according to claim 30 wherein the displacement element is adapted to move the storage medium past the head block.

34. A data transfer device according to claim 30 wherein tape is adapted to rewind tape to bring a data storage element back up for second element, tape having gone under it before to get the first element.

35. A data transfer device according to claim 30 wherein the device includes a control unit and wherein the transfer elements are adapted to communicate with the control unit, in use.

36. A data transfer device according to claim 30 wherein the control unit includes a comparator adapted to compare a data element indicative of the data transferred from the data storage element by the at least one transfer element to a second data element.

37. A data transfer device according to claim 30 wherein the transfer elements are of a type selected from the following list:
(i) write heads
(ii) read heads
(iii) combination of both read and write heads
(iv) a combined read-write head.

38. A data transfer device according to claim 30 wherein the data storage medium is selected from the following list:
(i) a magnetic tape
(ii) a magneto-optical disc
(iii) a magnetic disc
(iv) a re-writeable C.D.
(v) a mini-disc

39. A data transfer device according to 30 wherein the data transfer device is selected from the following list:
(i) a tape drive
(ii) a magnetic disc drive
(iii) a C.D. drive
(iv) a mini-disc drive

40. A method of reading data from a data storage medium comprising the steps of:
(i) providing a plurality of data transfer elements;
(ii) reading said data from a data storage element of the storage medium via a first data transfer element;
(iii) error checking a data element indicative of the data read from the storage medium via the first data transfer element; and
(iv) reading said data from said data storage medium via a second transfer element if the comparison of step iii) results in an error signal.

41. A method of reading data according to claim 40 comprising aligning the second transfer element with both the first transfer element and the data storage element and having the plurality of data transfer elements in a fixed position.

42. A method of reading data according to claim 40 comprising actuating a displacement element so as to effect a relative displacement of the storage medium and the plurality of data transfer elements.

43. A method of reading data according to claim 42 comprising the displacement element acting upon the data transfer elements.

44. A method of reading data according to claim 42 comprising the displacement element acting upon the data storage medium.

45. A method of reading data according to claim 40 comprising executing of a cyclic redundancy check upon said data elements.

46. A method of reading data according to claim 40 comprising executing steps ii) and iii) up to a pre-determined number of times prior to executing step iv) if the initial repetition of steps ii) and iii) does not avoid the production of an error signal.

47. A method of reading data according to claim 46 not executing step iv) if any one of the comparisons results in a match.

48. A method of reading data according to claim 40 comprising reporting a read error to a user of the storage medium if steps i) to iv) of the method are repeated more than a pre-determined number of times during a single read operation.

49. A method of reading data according to claim 40 comprising providing the data storage medium in a form selected from the following list:
(i) a magnetic tape
(ii) a magneto-optical disc
(iii) a magnetic disc
(iv) a C.D.
(v) a mini-disc

50. A data transfer tape device adapted to transfer data to a data storage tape having a data storage track;
the data transfer device comprising:
first and second data transfer elements;
a displacement element;
a control unit including a comparator;
the data transfer elements being arranged such that, when, in use, the data storage tape is moving past the transfer elements the data storage track is aligned therewith;
the comparator being arranged to error check data written to the data storage medium; and
the displacement element being arranged to achieve, in use, relative transverse displacement between said transfer elements and transfer zones such that either the first or the second transfer elements is selectively alignable with the data track, in use, in response to the instruction from the control unit.

51. A machine readable data carrier having encoded upon it instructions to control a control processor of a data transfer device having first and second read/write data transfer heads, a data recording medium having a read/write zone adjacent the heads, a multi-channel recording medium provided in the zone adjacent the heads, and a head to channel alignment device adapted to control the relative position, transverse to the direction of movement of the medium past the heads, of the heads and the channels of the medium, the instructions causing the control processor to read or write data to or from a channel on the recording medium and to check the read or written data for errors, and upon detecting an error the instructions causing the control processor to control the alignment device to align the channel which caused the error signal with a different head to that which was used in the read/write operation which resulted in an error signal.

52. A method of reading data from a data carrier using a device with first and second data transfer heads arranged in a read-after-write configuration with both heads aligned with a common data track comprising attempting to read the data from the data carrier using the first head and subsequently reading the data using the second head.

53. A method as claimed in claim 52 wherein the second head is used to read the data if the first head has difficulty reading it.

54. A method as claimed in claim 52 wherein the second head is a write head capable of writing data to the carrier as well as reading data from the data carrier.

55. A method as claimed in claim 52 wherein the method comprises determining that the first head has not read data of a region of the data carrier properly and advancing or rewinding said region to align it with the second head.

56. A method as claimed in claim 52 wherein the data carrier comprises a tape which moves past the second head before it encounters the first head and the tape is rewound in order to read a section of the tape with the second head.

57. A data transfer device arranged to read data from a data carrier comprising data transfer heads arranged in a read-after-write configuration having both heads arranged to be aligned with a common data track of the data carrier, the first head arranged to read data from the data carrier and the second head subsequently arranged to read data from the data carrier.

58. A device according to claim 57 wherein the second head is arranged to read the data if the first head has difficulty reading it.

59. A device according to claim 57 wherein the second head is a write head arranged to be capable of both reading and writing data carrier.

60. A device according to claim 57 wherein the device is arranged to determine that the first head has not read data of a region of the data carrier properly and advancing, or rewinding said region to align it with the second head.

61. A device according to claim 57 wherein the data carrier is a tape which is arranged to move past the second head prior to encountering the first head and the tape is rewound in order to read a section of the tape with the second head.
